(19) United States
(12) Patent Application Publication
(10) Pub. No.: US 2012/0025841 A1
(43) Pub. Date: Feb. 2, 2012

(54) CAPACITANCE MEASUREMENT IN MICROCHIPS

(75) Inventors: Jaemin Kim, Leuven (BE); Geert Van der Plas, Leuven (BE); Paul Marchal, Blanden (BE)

(73) Assignee: IMEC, Leuven (BE)

(21) Appl. No.: 13/194,861

(22) Filed: Jul. 29, 2011

Related U.S. Application Data
(60) Provisional application No. 61/368,878, filed on Jul. 29, 2010.

(51) Int. Cl. G01R 31/02

(52) U.S. Cl. 324/537

(57) ABSTRACT

A measurement system for determining the capacitance of a device-under-test in an integrated circuit is disclosed. In one aspect, the measurement system has a reference circuit and a test circuit. Each circuit has first and second diodes that are switched in accordance with a clock cycle to charge and discharge the associated circuit. A method takes average current measurements for each circuit at one voltage level and processes them so that the capacitance of a device-under-test connected to the test circuit can accurately and reliably be determined. Two voltage levels may be used and adjustments are made for voltage threshold of the diodes and also their resistance.

### CROSS REFERENCE TO RELATED APPLICATIONS

This application claims priority under 35 U.S.C. §119(e) to U.S. provisional patent application 61/368,878 filed on Jul. 29, 2010, which application is hereby incorporated by reference in its entirety.

### BACKGROUND OF THE INVENTION

1. Field of the Invention

The disclosed technology relates to capacitance measurement in microchips, and more particularly, although not exclusively, to capacitance measurement of interconnects in such microchips.

2. Description of the Related Technology

In three-dimensional (3D) stacked integrated circuits (ICs) leading high density and high performance system integrations, vertical interconnection structures such as through-silicon-vias (TSVs) and micro-bumps have recently been added in comparison to conventional integrated circuit (IC) technologies. These structures contain electrically parasitic capacitances due to their physical dimensions. These parasitic capacitances tend to degrade system performance in high frequency bandwidths, so they can no longer be considered to be negligible in high speed operating systems even though the values of such parasitic capacitances are very small, typically, only tens of IF (10⁻¹⁵ F).

Conventional measurement techniques for parasitic capacitances use charge-based capacitance measurement (CBCM) techniques as described in articles entitled “Application of charge based capacitance measurement (CBCM) technique in interconnect process development” by Bothra, S.; Rezvani, G.A.; Sur, H.; Fan, M.; Shenoy, J.N., Interconnect Technology Conference, 1998. Proceedings of the IEEE 1998 International, Publication Year: 1998, Page(s): 181 to 183 (Bothra et al.) and “An on-chip, attofarad interconnect charge-based capacitance measurement (CBCM) technique” by Chen, J.C.; McGaughy, B.W.; Sylvester, D.; Chenming Hu; Electron Devices Meeting, 1996, IEDM '96., International, Publication Year: 1996, Page(s): 69 to 72 (Chen et al.).

In the article by Bothra et al., a CBCM technique is described in which fF level inter-metal or interconnect capacitances between metal lines in different configurations are determined. Such parasitic capacitances are determined by a variety of interconnect structures with varying line width and spacing. The capacitance to be measured is connected in a circuit with n-channel metal oxide semiconductor field effect transistor (NMOS) and p-channel metal oxide semiconductor field effect transistor (PMOS) devices. Pulsing of gates in the NMOS and PMOS devices provides an average direct current which is proportional to the unknown capacitance. A reference structure is used to cancel parasitic capacitances due to the presence of junctions and metal lines, typically of the order of a few fF, by subtracting the capacitance from the result to provide the unknown capacitance value.

The article by Chen et al. describes on-chip or off-chip measurement techniques in which no reference capacitor is required and which can be used for the determination of interconnect geometry capacitances. A pseudo inverter configuration using NMOS and PMOS transistors, each having their own input gate, is connected to the interconnect whose capacitance is to be measured. One part of the pseudo inverter configuration is used as reference. The capacitance is determined from the slope of a graph of the network current and voltage applied to the pseudo inverter configuration.

In the capacitance measurement systems described above, the area of the test structure can be relatively large compared to the actual measurement device. In addition, a number of process steps are usually necessary for the construction of elements for the test structure.

### SUMMARY OF CERTAIN INVENTIVE ASPECTS

Certain inventive aspects relate to a measurement circuit for ICs that has a smaller area than conventional test structures.

Certain inventive aspects relate to a measurement circuit that can be implemented using fewer process steps compared to conventional capacitance measurement circuits.

In accordance with a first aspect of the present disclosure, there is provided a measurement system for measuring the capacitance of a device-under-test in an integrated circuit. The system comprises a first circuit forming a reference circuit, and a second circuit forming a device-under-test circuit and into which the device-under-test is connected, the second circuit being substantially identical to the first circuit. The first and second circuits each comprise a first diode and a second diode, the device-under-test being connected between the first and second diodes of the second circuit.

By using diodes instead of n-channel and p-channel metal oxide semiconductor field effect transistors (NMOS and PMOS respectively) as in a conventional pseudo inverter configuration, it is possible to reduce the area of the measurement circuit as less probing pads are required. It is also possible to reduce the number of process steps needed for the construction of the measurement circuit when compared to the number of process steps required in the conventional pseudo inverter configuration. As a result, measurements can be performed at earlier stages of wafer fabrication thereby enabling an early assessment of yield.

In one aspect, the measurement system and the method may provide the ability to measure the capacitance of an interconnection by making use of structures which can be manufactured without gate process steps. In the past techniques, many patents and papers have been presented which rely on standard CMOS technology. The CMOS device should involve all of N-well, gate, N+, and P+ process steps, whereas the measurement system and method in one inventive aspect only rely on structures which can be manufactured using only N+ and P+ process steps.

The first and second diodes each has a cathode and an anode, the cathode of the first diode being connected to the anode of the second diode in respective ones of the first and second circuits.

Each diode is switched on and off by applying a forward and a reverse bias respectively thereto.

In accordance with another aspect of the present disclosure, there is provided a method of measuring a capacitance value for a device-under-test using the measurement system described above. The method comprises a) connecting the device-under-test to the second circuit, b) charging the first circuit by applying a first voltage level thereto, c) measuring a first average current value of current flowing through the first circuit as it is charged, d) charging the second circuit by applying the first voltage level thereto, e) measuring a second average current value of current flowing through the second circuit as it is charged, and f) determining the capacitance value for the device-under-test from at least the measured first and second average current values and the first voltage level.

In one aspect of the present disclosure, the method can estimate the capacitance of a device-under-test only with the PN diode manufacturing process such as typical MEMS manufacturing processes.

The process c) may further comprise applying a forward bias to the first diode and a reverse bias to the second diode so that the first circuit is charged, and discharging the first circuit by applying a reverse bias to the first diode and a forward bias to the second diode.

In addition, the process e) may further comprise applying a forward bias to the first diode and a reverse bias to the second diode so that the second circuit is charged, and discharging the second circuit by applying a reverse bias to the first diode and a forward bias to the second diode.

In one aspect, the method may further comprise g) charging the first circuit by applying a second voltage level thereto, h) measuring a third average current value of current flowing through the first circuit as it is charged, i) charging the second circuit by applying the second voltage level thereto, j) measuring a fourth average current value of current flowing through the second circuit as it is charged, and wherein the process f) comprises determining the capacitance of the device-under-test from at least the measured first, second, third and average current values and the first and second voltage levels.

The process f) may further comprise adjusting the capacitance value for the device-under-test in accordance with a threshold voltage level of the first and second diodes of the first and second circuits.

In addition, the process f) may further comprise adjusting the capacitance value for the device-under-test in accordance with a voltage difference due to turn-off resistance of the first and second diodes.

A clock cycle may be used to time the charging and discharging of the first and second circuits.

### BRIEF DESCRIPTION OF THE DRAWINGS

For a better understanding of the present disclosure, reference will now be made, by way of example only, to the accompanying drawings in which:

FIG. 1 illustrates a conventional CBCM method using a pseudo inverter structure;

FIG. 2 illustrates a comparison between test structures and their respective areas for measurements where (a) shows the test area for a CMOS device based method and (b) shows the test area for a diode based device in accordance with one embodiment;

FIG. 3 illustrates a schematic representation of one embodiment;

FIG. 4 illustrates a schematic representation of one embodiment that can be used to measure the capacitance of a through-silicon-via (TSV);

FIG. 5 illustrates time domain waveforms of applied clock signals at charging and discharging nodes, the charging and discharging diodes turning on and off at the charging and discharging periods respectively;

FIG. 6 illustrates time domain waveforms of applied clock signals and floating node voltages with a diode threshold voltage effect;

FIG. 7 illustrates time domain waveforms of applied clock signals and floating node voltages with a diode turn-off resistance effect;

FIG. 8 illustrates time domain waveforms of two kinds of applied clock signals for the method according to one embodiment;

FIG. 9 illustrates a flow chart showing the steps for the calculation of device-under-test (DUT) capacitance in accordance with the method in one embodiment; and

FIG. 10 illustrates comparisons between error values obtained in capacitance values between a conventional measurement method and the method in accordance with one embodiment for (a) width and length variations of a diode, (b) clock period variation, (c) first applied voltage variation, (d) DUT capacitance variation, (e) reference capacitance variation, and (f) diode voltage threshold variation.

### DETAILED DESCRIPTION OF CERTAIN ILLUSTRATIVE EMBODIMENTS

The present disclosure will be described with respect to particular embodiments and with reference to certain drawings but the disclosure is not limited thereto. The drawings described are only schematic and are non-limiting. In the drawings, the size of some of the elements may be exaggerated and not drawn on scale for illustrative purposes.

It will be understood that the terms “vertical” and “horizontal” are used herein refer to particular orientations of the Figures and these terms are not limitations to the specific embodiments described herein.

The move towards newer and smaller technologies is linked to scaling induced problems such as process variations. A method for measuring the capacitance of an interconnection or other device-under-test (DUT) is described below which can used in such technologies. The method enables the measurement of the capacitance of the interconnection or DUT, independently of any possible process variations.

Certain embodiments will be described with reference to the measurement of the parasitic capacitance of vertical interconnections based on CBCM (charge based capacitance measurement) by using two diodes and controlling signals on diodes. In one embodiment, a method and system are disclosed to measure the parasitic capacitance of interconnections in a microchip. A diode-based capacitance measurement technique and a process variation de-embedding technique are also described.

In one particular embodiment of the present disclosure, the system and related method is applied to TSVs. However, it should be noted that system and method can also be used in traditional two-dimensional (2D) interconnection technologies and other 3D interconnection technologies. The system and method can be used to measure the capacitance of any interconnection in electronic circuits.

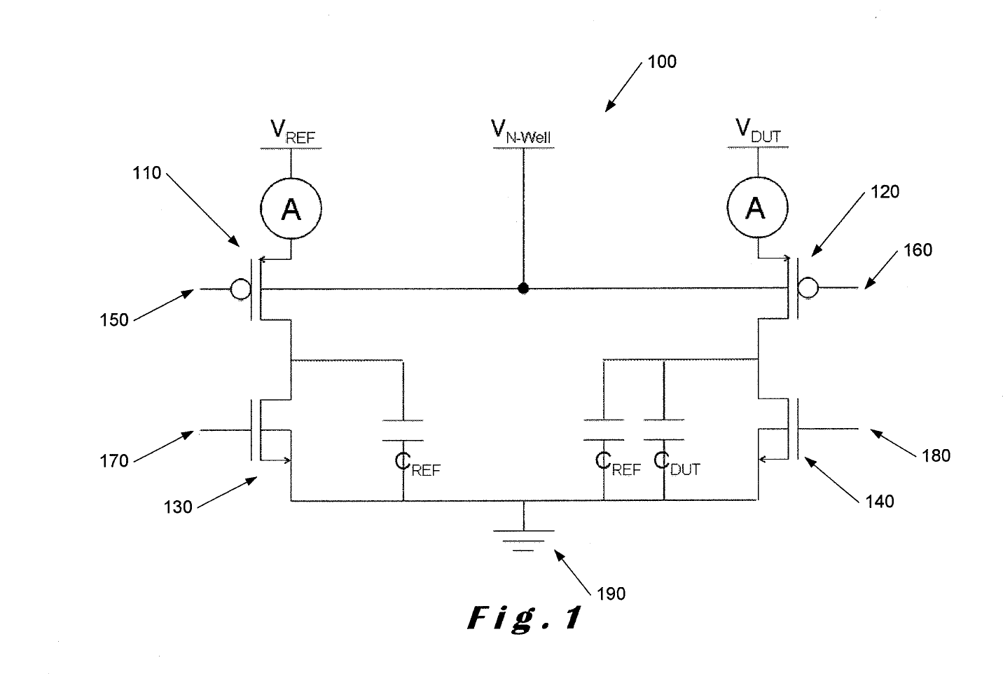

Referring initially to FIG. 1, a conventional CBCM method is shown that uses a pseudo inverter configuration 100 requiring manufacturing processes for both NMOS and PMOS. The pseudo inverter configuration 100 comprises first and second PMOS devices 110, 120, and first and second NMOS devices 130, 140, each device having a signal input gate 150, 160, 170, 180 as shown. PMOS devices 110, 120 are connected to receive a reference voltage, V_{REF}, a voltage corresponding to an n-well, V_{N-WELL}, and a voltage for the DUT, V_{DUT}, as shown. The NMOS devices 130, 140 are connected to the ground 190 and reference capacitances, C_{REF}, are provided between each NMOS device and ground. In addition, a capacitance relating to the DUT, C_{DUT}, is also provided as shown.

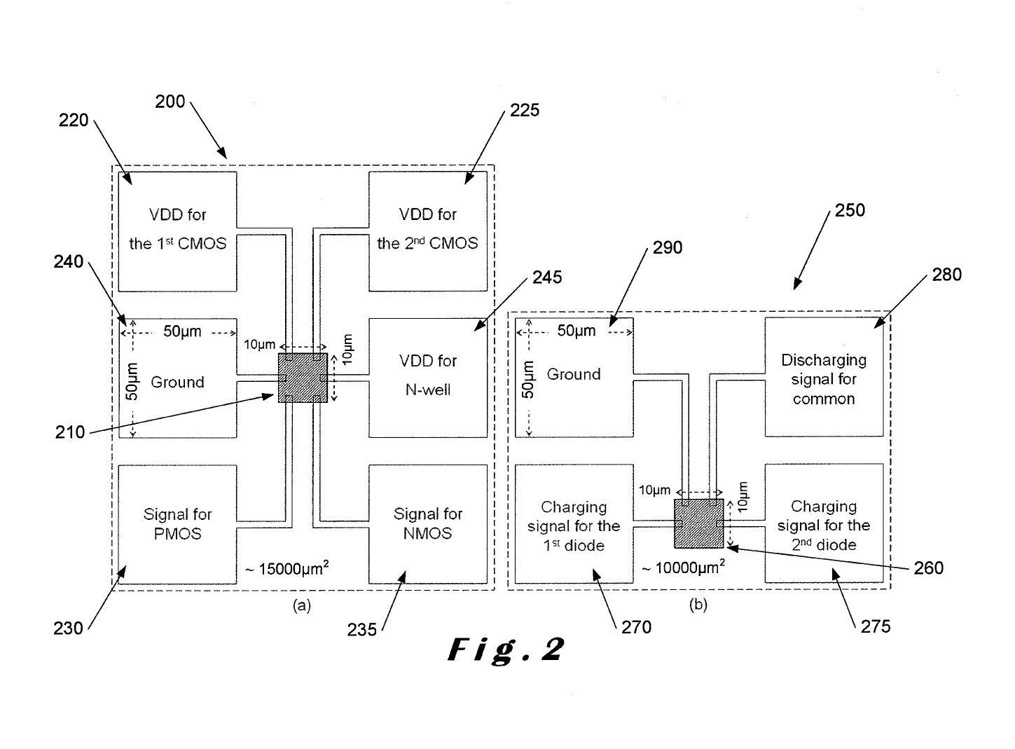

FIG. 2 illustrates the required area to set test structures when CMOS devices, described above with reference to FIG. 1, are used, as shown at (a). The test area for diode devices in accordance with one embodiment are shown at (b).

A CMOS test structure 200 is shown at (a) that comprises a measuring device 210 connected to voltage pads 220, 225, signal pads 230, 235, a ground pad 240, and a voltage pad for N-well 245.

A diode test structure 250 in accordance with one embodiment is shown at (b). A measuring device 260 is shown connected to charging signal pads 270, 275, a discharging signal pad 280 and to ground pad 290.

It is assumed that the measuring devices 210, 260, such as a CMOS device in (a) or a diode device in (b) have a size of 10 μm-by-10 μm and the probing pads each have a size of 50 μm-by-50 μm. As shown in (b), a single discharge pad is required and, therefore, the diode devices have a simpler configuration and a reduced test structure area of approximately, up to 33% (two less probing pads required) compared to the conventional CMOS-based test structure. As shown, a total area of approximately 150000 μm² is required for the CMOS test structure compared to only approximately 100004 μm² for the test structure in one embodiment for the same measuring device size of approximately 100 μm².

In particular, the prior art requires four process steps, namely, P+, N+, N− well, and gate. In contrast one embodiment provides a measurement system without a gate process and there are only two process steps required, namely, P+ and N+.

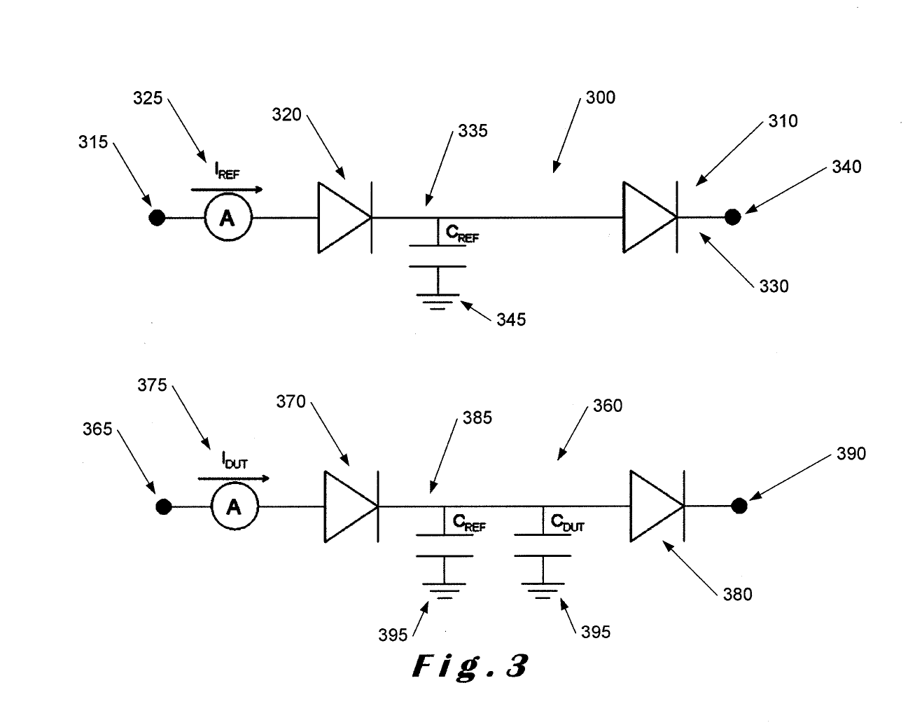

FIG. 3 illustrates a schematic representation of a test system 300 in accordance with one embodiment. The system 300 comprises two circuits: a reference circuit 310, and a device-under-test (DUT) circuit 360 that includes the capacitance to be measured. Each circuit 310, 360 has a charging node 315, 365 connected to a charging diode 320, 370 via an ammeter 325, 375. The charging diode 320, 370 is connected to a discharging diode 330, 380 via a line 335, 385 and then to a discharging node 340, 390 as shown. Both circuits 310, 360 also contain a reference capacitance, C_{REF}, connected to the line 335, 385 and to ground 345, 395 as shown. In addition, the DUT circuit 360 includes a capacitance, C_{DUT}, which corresponds to the DUT being tested. C_{DUT} is also connected to line 385 and to ground 395.

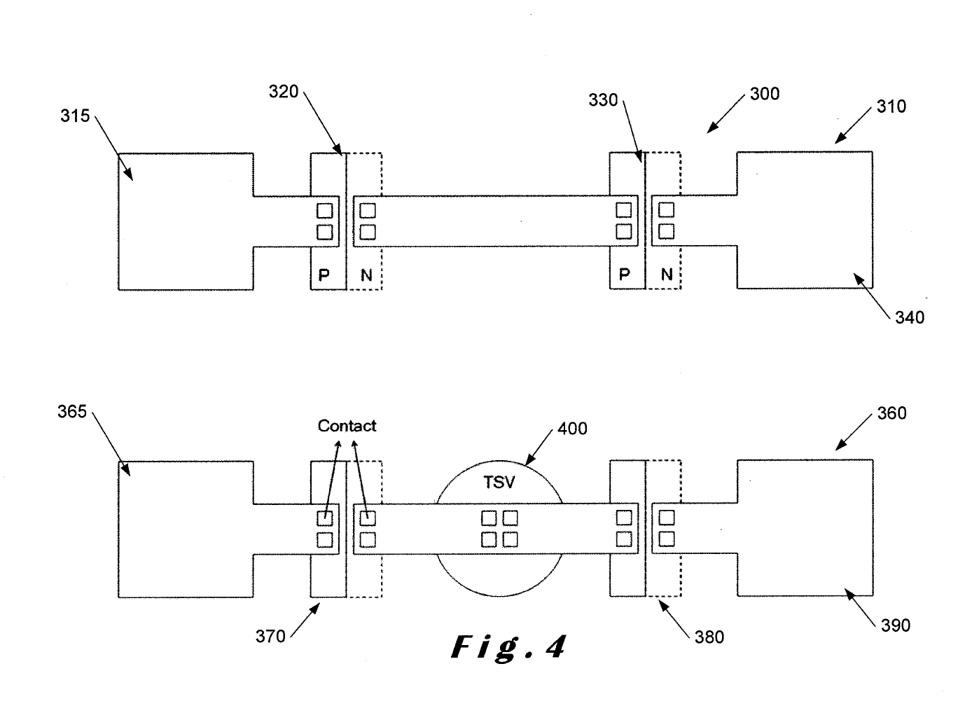

One use of certain embodiments is to measure the capacitance of a TSV 400 which is widely applied in 3D interconnection technology. FIG. 4 illustrates a top view of the system 300 in accordance with one embodiment. Components that have previously been described with reference to FIG. 3 are numbered the same.

As before, the test structure 300 comprises a reference circuit 310 and a DUT circuit 360, each circuit having a charging node 315, 365 connected to a charging diode 320, 370, a discharging diode 330, 380, and a discharging node 340, 390 as shown. The TSV 400 is located in the DUT circuit 360 between the charging diode 370 and the discharging diode 380. As before, each circuit 310, 360 has the same configuration with the exception of the positioning of the TSV 400 in the DUT circuit 360.

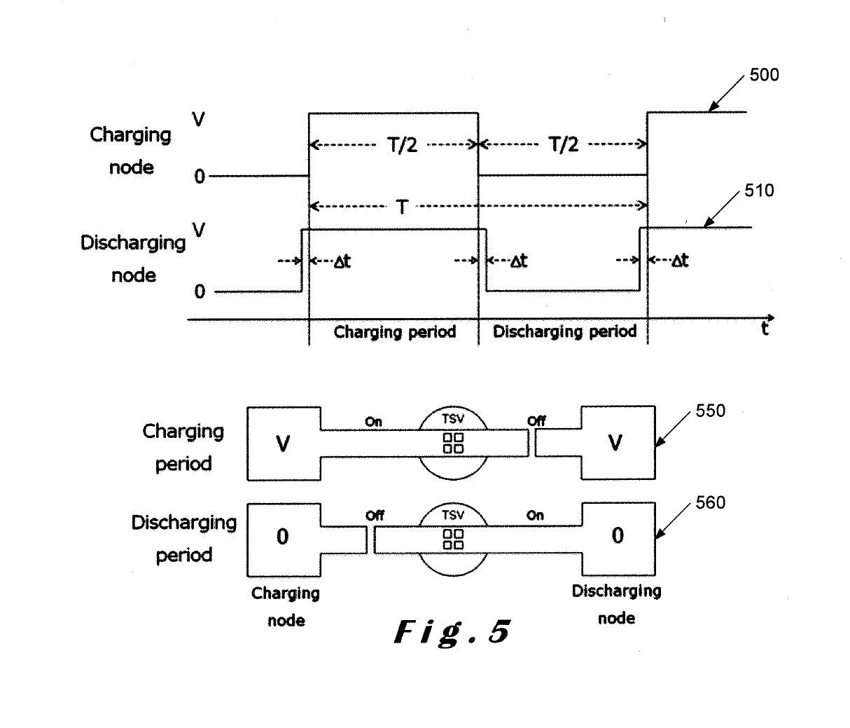

Operation of the test structure 300 in accordance with one embodiment will now be described with reference to FIG. 5. In FIG. 5, two clock signals and switching on and off of the charging and discharging diodes are shown. Basically, a simple clock signal is used for the measurement. In order to control turning on and off of charging and discharging diodes independently, the two clock signals depicted in FIG. 5 are applied on the charging and discharging nodes respectively as shown by clock signal 500 for the charging node and clock signal 510 for the discharging node. The DUT circuit of FIGS. 3 and 4 is also shown for the charging period and the discharging period where the charging diode is on and the discharging diode is off during charging and the charging diode is off and the discharging diode is on during discharging. This is shown by the circuits indicated as 550 and 560 respectively. Naturally, the reference circuit is also present but is not shown for ease of explanation. In addition, the reference circuit operates the same way as the DUT circuit.

The two clock signals have the same time period, T, but having slightly different duty cycles. As shown, the discharging node has a charging period of T/2+2Δt and a discharging period of T/2−2Δt. When charging, only the charging diode is turned on and the discharging diode is turned off. Therefore, the voltage applied at the charging node starts to charge the capacitance in the TSV located between two diodes and the current flows into the capacitance. In contrast, during discharging, only the discharging diode is turned on and the charging diode is turned off. The capacitance starts to drain charges from the capacitance to the discharging node. According to this switching mechanism, the turn-on and turn-off of two charging and discharging diodes are controlled in both the reference circuit (not shown) and the DUT circuit.

When the clock signal with the deterministic voltage is enforced to the capacitor and the average current value through the capacitor is measured, the capacitance can be calculated as follows:

$$C = \frac{T \times {I}_{AVG}}{V} \qquad ( 1 )$$

where

C is the capacitance of the target structure, the TSV in this case;

T is the time period of clock signal;

I_{AVG} is the average value of measured current waveform through the DUT capacitance; and

V is the deterministic voltage level of clock signal applied to the capacitance.

In the simplest case, allowing for the capacitance of the rest of the circuit, the capacitance of the DUT, C_{DUT}, is determined as the difference between the equation (1) for the DUT circuit and equation (1) for the reference circuit. In particular, the capacitance of the DUT, C_{DUT}, can be determined as follows:

$${C}_{DUT } = \frac{T ( {I}_{{AVG}_{DUT}} - {I}_{{AVG}_{REF}} )}{V}$$

where

I_{AVG DUT} and I_{AVG REF} refer to the average current values in the DUT circuit and the reference circuit respectively.

It should be noted that the direct applied voltage to the capacitance is V in equation (1) for the calculation. However, the threshold voltage of diode distorts the value of V, so equation (1) is not necessarily valid for all measurements.

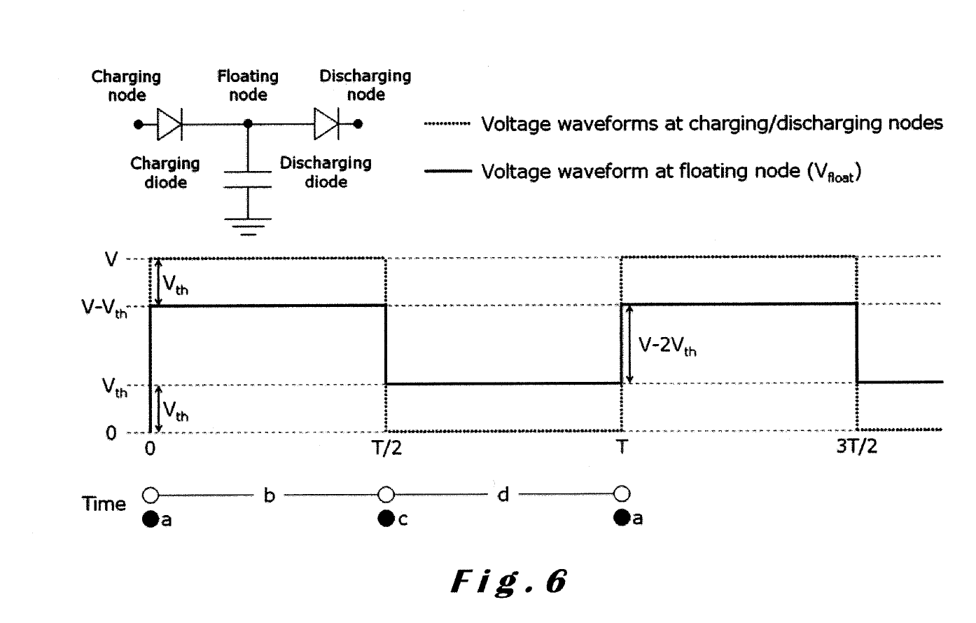

FIG. 6 illustrates the principle of voltage distortion. It is assumed that Δt in FIG. 5 is small enough to be negligible compared to T in FIG. 5, so clock signals at charging and discharging nodes have the same waveform as shown in FIG. 6.

At the point ‘a’ in FIG. 6, the charging diode is turned on and the current starts to flow into the DUT, as indicated by the capacitor attached to the floating node, in a very short time due to small resistance of the charging diode. When the voltage at the floating node, V_{float}, the node to which the DUT is connected, reaches to V−Vₜₕ, where Vₜₕ is the threshold voltage of the diodes, the charging diode is turned off because the voltage between P and N nodes is lower than Vₜₕ. Therefore, V_{float} keeps V−Vₜₕ level during the period ‘b’.

When the voltage on each of the charging and discharging nodes goes to zero at point ‘c’, the discharging diode is turned on and the charge retained within the DUT flows to the discharging node. V_{float} rapidly decreases and stops at the Vₜₕ level because the discharging diode is turned off due to lower voltage than the threshold voltage, Vₜₕ, and, the voltage at the floating node, V_{float}, holds the threshold voltage, Vₜₕ, during the period ‘d’. The charging diode is turned on again, and the switching mechanism described above is repeated.

It will be appreciated that each diode has a cathode and an anode, the cathode of the first diode being connected to the anode of the second diode in the reference and DUT circuits, the DUT being placed between the cathode of the first diode and the anode of the second diode in the DUT circuit. It will also be appreciated that each diode is turned on by applying a forward bias thereto and a turned off by applying a reverse bias thereto. As a result, in the charging part of the clock cycle, the first diode is forward biased and the second diode is reverse biased and in the discharging part of the clock cycle, the first diode is reverse biased and the second diode is forward biased.

Accordingly, the applied voltage to the DUT swings from Vₜₕ to V−Vₜₕ, not from 0 to V due to the threshold voltages of diodes. Therefore, the equation (1) for capacitance calculation can be revised as follows:

$$C = \frac{T \times {I}_{AVG}}{V - 2 {V}_{th}} \qquad ( 2 )$$

where
Vₜₕ is the threshold voltage of charging and discharging diodes; and the definitions of other parameters are same as given above in relation to equation (1).

Similarly, as described above with reference to equation (1), the DUT capacitance, C_{DUT}, is determined as:

$${C}_{DUT} = \frac{T ( {I}_{{AVG}_{DUT}} - {I}_{{AVG}_{REF}} )}{V - 2 {V}_{th}}$$

Ideally, in one embodiment, the resistance of the diodes is infinite when the diode is turned off with a voltage that is lower than Vₜₕ. However, this diode turn-off resistance, R_{off}, has finite value in a real device and it generates another factor to be considered for the calculation.

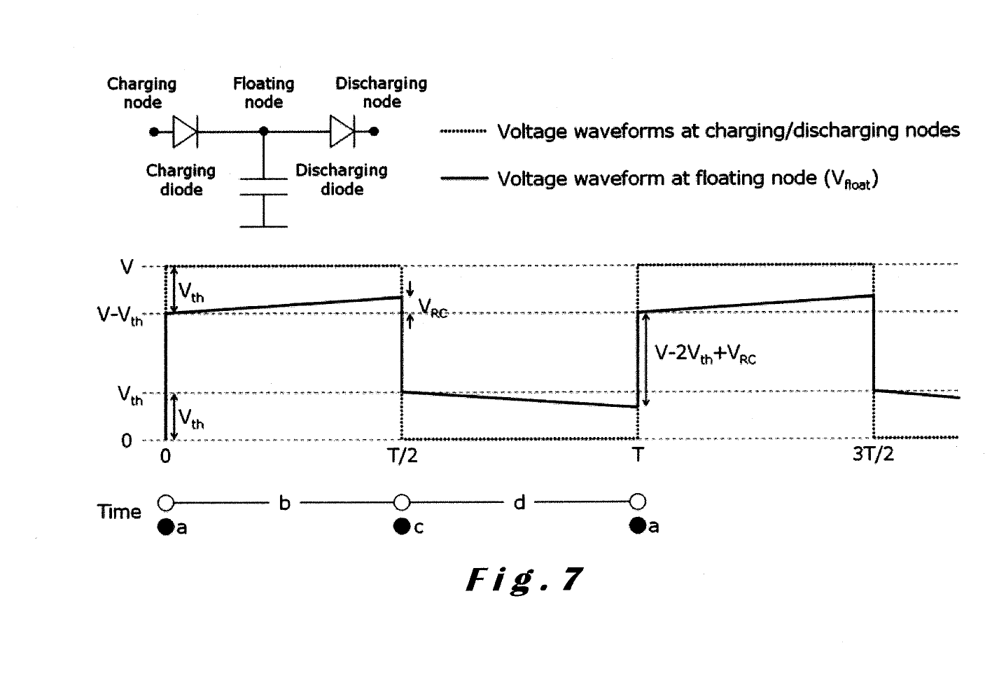

FIG. 7 represents the effect of R_{off}. At the period ‘b’, V_{float} increases continuously according to the elapsed time because the applied voltages at charging and discharging nodes supply charge to the DUT through the finite resistance of the turned-off diode. After the voltages at charging and discharging nodes are changed to zero at the point ‘c’ and the V_{float} goes to Vₜₕ, V_{float} cannot keep Vₜₕ during the period ‘d’ and becomes lower than Vₜₕ when both the charging and discharging nodes turned on again at the point ‘a’ as shown in FIG. 7 for the same reason.

Therefore, this voltage difference, which is defined as V_{RC} because it comes from the RC constant of diode turn-off resistance and capacitance in the structure, should be included in the calculation. The equation for capacitance calculation should be revised as:

$$C = \frac{T \times {I}_{AVG}}{V - 2 {V}_{th} + {V}_{RC}} \qquad ( 3 )$$

where

V_{RC} is the voltage difference from RC constant of diode turn-off resistance and capacitance in the structure; and the definitions of other parameters are same as given in equation (2) above.

V_{RC} is determined by the diode turn-off resistance, R_{off}, the capacitance in the structure, and the time period and duty cycle of clock signals at charging and discharging nodes (T/2 and T in FIG. 7).

In order to use equation (3), both Vₜₕ and V_{RC} have to be provided with accurate values for the calculation. However, Vₜₕ and R_{off} normally vary depending on process variations even though they are provided from datasheet. Moreover, the capacitance in the DUT circuit cannot be applied because it includes the capacitance value that is to be obtained from the measurement.

In one embodiment, Vₜₕ and V_{RC} in equation (3) need to be de-embedded so that an accurate capacitance value of target structure can be extracted.

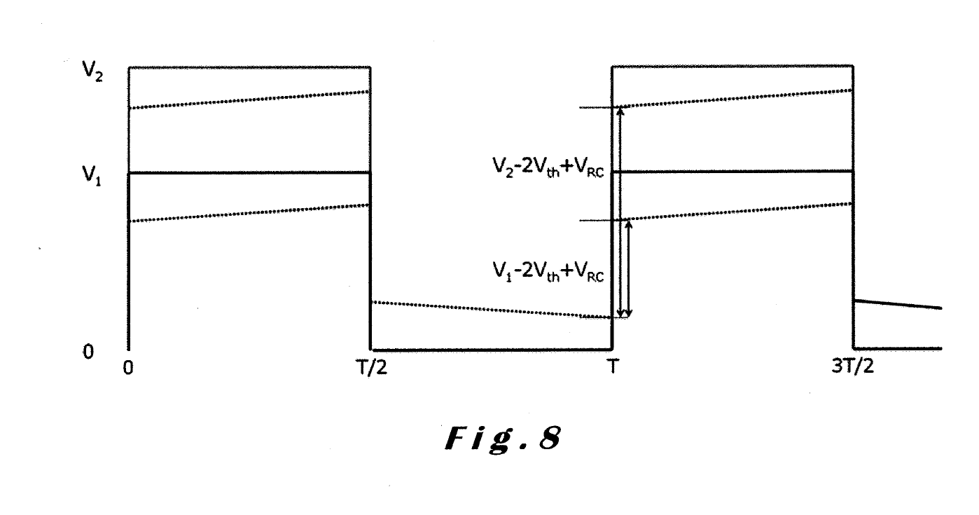

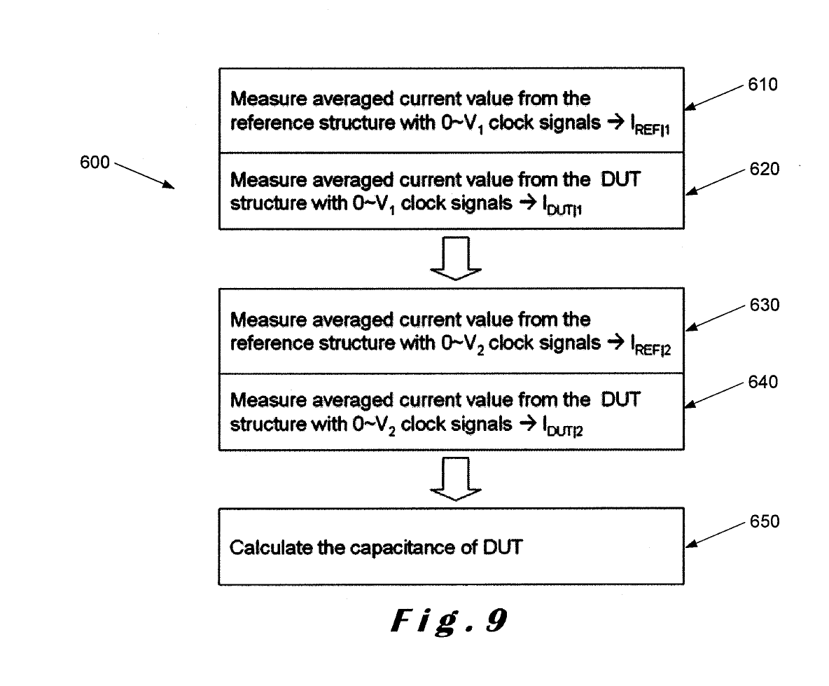

The basic principle of de-embedding in accordance with one embodiment will now be described with reference to the graph shown in FIG. 8 and the flow chart shown in FIG. 9. First, clock signals which swing from 0 to V₁ with a time period, T, and an arbitrary duty cycle are applied to both the reference and DUT structures discussed above with reference to FIGS. 3 and 4. The voltage level of V₁ must be larger than 2Vₜₕ as described with reference to FIG. 6. Then, the average current values from the reference structure (I_{REF|1}) and the DUT structure (I_{DUT|1}) are measured. By subtracting two equations, the capacitance of the DUT can be determined as:

$${C}_{DUT} = \frac{T \times ( {I}_{DUT \vert 1} - {I}_{REF \vert 1} )}{{V}_{1} - 2 {V}_{th} + {V}_{RC}} \qquad ( 4 )$$

Similarly, clock signals which swing from 0 to V₂ with the same timing configuration are applied and the two average current values (I_{REF|2} and I_{DUT|2}) are measured again. The voltage level of V₂ must be larger than 2Vₜₕ as well. From these steps, the capacitance of the DUT can be determined as:

$${C}_{DUT} = \frac{T \times ( {I}_{DUT \vert 2} - {I}_{REF \vert 2} ) }{{V}_{2} - 2 {V}_{th} + {V}_{RC}} \qquad ( 5 )$$

Because two measurements are using the fabricated diodes which have the same electrical properties, Vₜₕ has an identical value for each of equations (4) and (5) above even though the process variation can slightly change the value. In addition, V_{RC} also has an identical value regardless the process variation due to uses of the same turn-off resistance, capacitance in the structure, and timing configuration of clock signal in two measurement procedures. When the equations (4) and (5) are permuted by voltages parameters as shown in equations (6) and (7) below and subtracted as shown in equation (8), the capacitance of the DUT can be calculated using equation (9) using the disclosed structure and schematic.

$$\begin{matrix}{V}_{1} - 2 {V}_{th} + {V}_{RC} = \frac{T \times ( {I}_{DUT \vert 1} - {I}_{REF \vert 1} )}{{C}_{DUT }} & ( 6 ) \\ {V}_{2} - 2 {V}_{th} + {V}_{RC} = \frac{T \times ( {I}_{DUT \vert 2} - {I}_{REF \vert 2} )}{{C}_{DUT}} & ( 7 ) \\ {V}_{1} - {V}_{2} = \frac{T \times ⌊ ( {I}_{DUT \vert 1} - {I}_{REF \vert 1} ) - ( {I}_{DUT \vert 2} - {I}_{REF \vert 2} ) ⌋}{{C}_{DUT}} & ( 8 ) \\ {C}_{DUT} = \frac{T \times ⌊ ( {I}_{DUT \vert 1} - {I}_{REF \vert 1} ) - ( {I}_{DUT \vert 2} - {I}_{REF \vert 2} ) ⌋}{{V}_{1} - {V}_{2}} & ( 9 )\end{matrix}$$

where

C_{DUT} is the capacitance of DUT;

T is the time period of clock signal;

I_{REF|1} is the average current value from the reference structure with 0-V₁ clock signals;

I_{DUT|1} is the average current value from the DUT structure with 0-V₁ clock signals;

I_{REF|2} is the average current value from the reference structure with 0-V₂ clock signals; and

I_{DUT|2} is the average current value from the DUT structure with 0-V₂ clock signals.

In the flow chart 600 shown in FIG. 9, the first step, step 610, is to measure an averaged current value, I_{REF|1}, from the reference structure 310 (as shown in FIGS. 3 and 4 above) with clock signals ranging between 0 and V₁. At the same time, in step 620, an averaged current value, I_{DUT|1}, is measured from the test structure 360 (as shown in FIGS. 3 and 4 above) with clock signals ranging between 0 and V₁. The next steps correspond to steps 610 and 620 but for clock signals between 0 and V₂, as shown in steps 630 and 640, to provide, I_{REF|2}, from the reference structure 310 (as shown in FIGS. 3 and 4 above) and I_{DUT|2}, from the test structure 360. The capacitance of the DUT is then calculated using equation (9) in step 650.

The method and system in one embodiment were verified by simulations where the following parameters and values were used:

| Symbol | Description | Value |
|---|---|---|
| W | Width of a diode (μm) | 3.16 |
| L | Length of a diode (μm) | 3.16 |
| T | Time period of clock signal (μs) | 5 |
| V₁ | V₁ voltage (V) | 2.5 |
| V₂ | V₂ voltage (V) | 1.5 |
| C_{DUT} | Capacitance of DUT (fF) | 100 |
| C_{REF} | Capacitance of reference structure (pF) | 1 |
| Vₜₕ | Threshold voltage of a diode (sim type) | typical |

Three specific parameter changes were made as shown below whilst keeping the other parameters at their typical values:

| | A | B | C |
|---|---|---|---|
| W&L variation (μm) | W = 10 | W = 3.16 | W = 1 |
| | L = 1 | L = 3.16 | L = 10 |
| Clock period variation (μs) | 1 | 5 | 10 |
| V₁ variation (V) | 2 | 2.5 | 3 |
| DUT capacitance variation (fF) | 50 | 100 | 200 |
| Reference capacitance variation (pF) | 0.5 | 1 | 2 |
| Threshold voltage variation (sim type) | slow | typical | fast |

In addition, the capacitance of DUT was calculated using the conventional method, which is described in equation (2) by applying V₁ to V₂ in order to compare the accuracy of certain embodiments with respect to conventional measurement techniques.

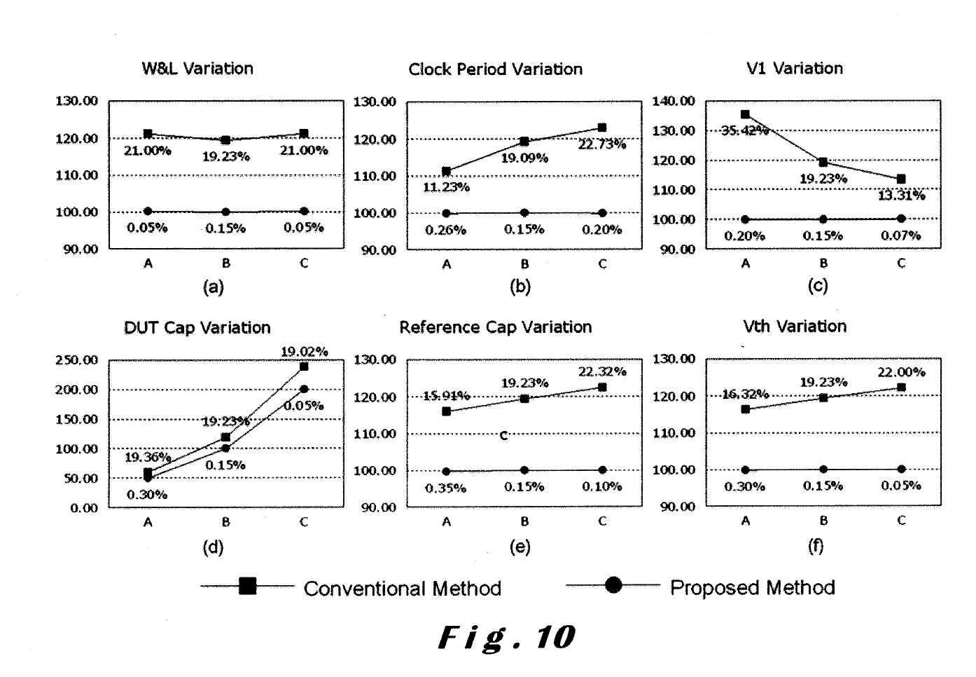

The results obtained were compared and are shown in FIG. 10 where a conventional method is indicated by the square marked line, and the method in one embodiment is indicated by the circle marked line. For all cases, the method in one embodiment, which uses diode based structures and de-embedding method, shows less than 0.35% errors for the target values, whereas the maximum error of conventional method is up to approximately 35%.

These simulation results and comparisons show that the method and system according to certain embodiments provide high reliability as well as high accuracy. In particular, the method can also calculate very accurate capacitance values even though the capacitance of DUT has small values as shown in (d), the reference capacitance is varied as shown in (e) and the threshold voltage of a diode is changed as shown in (f).

The foregoing description details certain embodiments of the disclosure. It will be appreciated, however, that no matter how detailed the foregoing appears in text, the disclosure may be practiced in many ways. It should be noted that the use of particular terminology when describing certain features or aspects of the disclosure should not be taken to imply that the terminology is being re-defined herein to be restricted to including any specific characteristics of the features or aspects of the disclosure with which that terminology is associated.

While the above detailed description has shown, described, and pointed out novel features of the disclosure as applied to various embodiments, it will be understood that various omissions, substitutions, and changes in the form and details of the device or process illustrated may be made by those skilled in the technology without departing from the disclosure.

What is claimed is:

1. A measurement system for measuring the capacitance of a device-under-test in an integrated circuit, the system comprising:
a first circuit forming a reference circuit; and
a second circuit forming a device-under-test circuit into which a device-under-test is connected, the second circuit being substantially identical to the first circuit,
wherein the first and second circuits each comprise a first diode and a second diode, the device-under-test being connected between the first and second diodes of the second circuit.

2. The measurement system according to claim 1, wherein the first and second diodes each has a cathode and an anode, the cathode of the first diode being connected to the anode of the second diode in respective ones of the first and second circuits.

3. The measurement system according to claim 1, wherein each diode is switched on and off by applying a forward and a reverse bias respectively thereto.

4. A method of measuring a capacitance value for a device-under-test using a system comprising a first circuit and a second circuit into which the device-under-test is connected, the second circuit being substantially identical to the first circuit, the method comprising:
a) connecting the device-under-test to the second circuit;
b) charging the first circuit by applying a first voltage level thereto;
c) measuring a first average current value of current flowing through the first circuit as it is charged;
d) charging the second circuit by applying the first voltage level thereto;
e) measuring a second average current value of current flowing through the second circuit as it is charged; and
f) determining a capacitance value for the device-under-test from at least the measured first and second average current values and the first voltage level.

5. The method according to claim 4, wherein the first and second circuits each comprise a first diode and a second diode, the device-under-test being connected between the first and second diodes of the second circuit, and wherein the process c) further comprises applying a forward bias to the first diode and a reverse bias to the second diode so that the first circuit is charged, and discharging the first circuit by applying a reverse bias to the first diode and a forward bias to the second diode.

6. The method according to claim 4, wherein the first and second circuits each comprise a first diode and a second diode, the device-under-test being connected between the first and second diodes of the second circuit, and wherein the process e) further comprises applying a forward bias to the first diode and a reverse bias to the second diode so that the second circuit is charged, and discharging the second circuit by applying a reverse bias to the first diode and a forward bias to the second diode.

7. The method according to claim 4, further comprising:
g) charging the first circuit by applying a second voltage level thereto;
h) measuring a third average current value of current flowing through the first circuit as it is charged;
i) charging the second circuit by applying the second voltage level thereto; and
j) measuring a fourth average current value of current flowing through the second circuit as it is charged,
wherein the process f) comprises determining the capacitance of the device-under-test from at least the measured first, second, third, and fourth average current values and the first and second voltage levels.

8. The method according to claim 7, wherein the first and second circuits each comprise a first diode and a second diode, the device-under-test being connected between the first and second diodes of the second circuit, and wherein the process f) further comprises adjusting the capacitance value for the device-under-test in accordance with a threshold voltage level of the first and second diodes of the first and second circuits.

9. The method according to claim 7, wherein the process f) further comprises adjusting the capacitance value for the device-under-test in accordance with a voltage difference due to turn-off resistance of the first and second diodes.

10. The method according to claim 4, wherein the process b) comprises using a clock cycle to time the charging and discharging of the first and second circuits.

11. The method according to claim 4, wherein the first and second circuits each comprise a first diode and a second diode, the device-under-test being connected between the first and second diodes of the second circuit.

12. The method according to claim 11, wherein the first and second diodes each has a cathode and an anode, the cathode of the first diode being connected to the anode of the second diode in respective ones of the first and second circuits.

13. The method according to claim 11, wherein each diode is switched on and off by applying a forward and a reverse bias respectively thereto.

14. A system for measuring a capacitance value for a device-under-test using a system comprising a first circuit and a second circuit into which the device-under-test is connected, the second circuit being substantially identical to the first circuit, the system comprising:
means for connecting the device-under-test to the second circuit;
means for charging the first circuit by applying a first voltage level thereto;
means for measuring a first average current value of current flowing through the first circuit as it is charged;
means for charging the second circuit by applying the first voltage level thereto;
means for measuring a second average current value of current flowing through the second circuit as it is charged; and
means for determining a capacitance value for the device-under-test from at least the measured first and second average current values and the first voltage level.

15. The system according to claim 14, wherein the first and second circuits each comprise a first diode and a second diode, the device-under-test being connected between the first and second diodes of the second circuit, and wherein the means for measuring a first average current value comprises means for applying a forward bias to the first diode and a reverse bias to the second diode so that the first circuit is charged, and means for discharging the first circuit by applying a reverse bias to the first diode and a forward bias to the second diode.

16. The system according to claim 14, wherein the first and second circuits each comprise a first diode and a second diode, the device-under-test being connected between the first and second diodes of the second circuit, and wherein the means for measuring a second average current value comprises means for applying a forward bias to the first diode and a reverse bias to the second diode so that the second circuit is charged, and means for discharging the second circuit by applying a reverse bias to the first diode and a forward bias to the second diode.

17. The system according to claim 14, further comprising:
means for charging the first circuit by applying a second voltage level thereto;
means for measuring a third average current value of current flowing through the first circuit as it is charged;
means for charging the second circuit by applying the second voltage level thereto; and
means for measuring a fourth average current value of current flowing through the second circuit as it is charged,
wherein the means for determining the capacitance value comprises means for determining the capacitance of the device-under-test from at least the measured first, second, third, and fourth average current values and the first and second voltage levels.

18. The system according to claim 17, wherein the first and second circuits each comprise a first diode and a second diode, the device-under-test being connected between the first and second diodes of the second circuit, and wherein the means for determining the capacitance value further comprises means for adjusting the capacitance value for the device-under-test in accordance with a threshold voltage level of the first and second diodes of the first and second circuits.

19. The system according to claim 17, wherein the means for determining the capacitance value further comprises means for adjusting the capacitance value for the device-under-test in accordance with a voltage difference due to turn-off resistance of the first and second diodes.

20. The system according to claim 14, wherein the means for charging the first circuit comprises means for using a clock cycle to time the charging and discharging of the first and second circuits.
